(19) United States
(12) Patent Application Publication
(10) Pub. No.: US 2008/0010815 A1
(43) Pub. Date: Jan. 17, 2008

(54) HEATING TAPE STRUCTURE

(75) Inventors: Goran Bajic, Belle River (CA); Dmitri Axakov, Waterloo (CA)

Correspondence Address: DOBRUSIN & THENNISCH PC, 29 W LAWRENCE ST, SUITE 210, PONTIAC, MI, 48342, US

(73) Assignee: W.E.T. Automotive Group AG

(21) Appl. No.: 11/776,869

(22) Filed: Jul. 12, 2007

Related U.S. Application Data
(60) Provisional application No. 60/807,547, filed on Jul. 17, 2006.

(51) Int. Cl. H05B 3/14; H05K 3/10

(52) U.S. Cl. 29/611; 29/846; 29/830

(57) ABSTRACT

There is described a heating tape structure and a method of forming the same. The heating tape structure includes a base film strip that is typically elongated and includes strips of conductive material extending adjacent sides of the base film strip. The heating tape can be formed by providing the base film strip to an automated system and layering the strips of conductive material thereon.

### CLAIM OF PRIORITY

This application claims the benefit of the filing dates of U.S. Provisional Application No. 60/807,547 filed Jul. 17, 2006.

### FIELD OF THE INVENTION

The present invention relates generally to heaters and more particularly to heating structures for use in a seat of automotive vehicles, transportation vehicles or other articles of manufacture.

### BACKGROUND OF THE INVENTION

In general, the present invention generally relates to a flexible heating structure for heating an article of manufacture, such as, for example a seat in an automotive vehicle. Polymer film heaters are commonly used to heat seats with a soft trim surface (e.g. leather surface). Polymer film heaters are typically comprised of a flat conductive film with a printed conductive network that is connected to a power source. These film heaters are known to include many good qualities, such as, low in cost, small in mass, and lifetime use. One drawback of using such heaters can involve the ability of the heaters to withstand harsh mechanical conditions. Read-through of the heater to the trim surface or other surface of a seat can also be a drawback. Furthermore, such heaters create unpleasant noise during ordinary movements by the user on a seat.

An additional potential drawback of film heaters can include their limited stretching ability, which subjects the film to significant tension.

Yet another drawback includes moisture build-up within the seat and the occupant contact areas. The film being solid and rectangular in shape is directly placed between the cushion and the trim surface of the seat as discussed above. Thus, a barrier is created for moisture generated by the occupant's skin. This barrier prevents the moisture from diffusing into a generally porous seat structure and can cause discomfort. “TotalHeat” or Thermal Solutions™ offers an example of a film heater of this kind.

Consequently, heaters were introduced to the market with holes on their film to eliminate the moisture issue. However, this solution did not eliminate the significant tension when the foam deflected. The foam of such seat was prone to developing cracks along the film edges on the heater's perimeter or holes.

Other heaters were introduced that used die cutting technology used to make flat film structures with stretching capabilities. These types of heaters included a film with conductive tracks created in one plane of the film. Typically, the conductive strips of these heaters were distanced from the film's edges because unavoidable edge stretching imposed risk to the conductive strips. As such, significant tension was imposed on the film's edges when a user occupied the seat. To withstand such tension, the heater needed to have a film with significant thickness. However, such a design placed many restrictions (e.g. shape, size and material choice) in the application of such heaters due to their read-through and noise issue.

One example of a heater that is designed to take on various shapes is disclosed in UK Patent Application GB2024579, which is incorporated herein by reference. However, the drawback of using this heater design is that it does not provide the flexibility and a thinness that is desirable for a vehicle seat.

The present invention proposes improved heating tapes and heating structures that can help eliminate one or combinations of the problems above and/or can provide other advantages that will become apparent throughout the description below.

### BRIEF DESCRIPTION OF THE DRAWINGS

The features and inventive aspects of the present invention will become more apparent upon reading the following detailed description, claims and drawings, of which the following is a brief description:

FIG. 1 is a perspective view an improved heating tape according to the present invention;

FIG. 2 is a cross sectional view of heating tapes;

FIG. 3 is a cross sectional view of heating tapes with at least one backing layer;

FIG. 4 is a cross sectional view of a heating tape arrangements according to the present invention;

FIG. 5 is a side view of heating tapes with more than two conductive strips;

FIG. 6 is a top view of a flexible heating tape structure according to the present invention;

FIG. 7 is a side view of a feeding tape according to the present invention;

FIG. 8 is a top view of the heating tape woven into a carrier according to the present invention;

FIGS. 9A and 9B are respectively a perspective view is a sectional view of an improved connector according to the present invention;

FIG. 10 is a perspective view of the connector with tails;

FIG. 11 is a top view of the connector with a hinge assembly;

FIG. 12 is a perspective view of the connector with a joint assembly;

FIG. 13 is a perspective view of a connector having X-intersecting heating tapes and feeding tapes;

FIG. 14 is a top view of the connector having L-intersecting heating tapes and feeding tapes;

FIG. 15 is top view of the connector having T-intersecting heating tapes and feeding tapes;

FIG. 16 is a perspective view of the connector with a lid;

FIG. 17 is a perspective view of the connector with a band;

FIG. 18 is a top view of the connector with a conductive conduit;

FIG. 19 is a top view of the connector with exposed two metal spots;

FIG. 20 is a top view of the connector with protrusions for positioning the tapes;

FIG. 21 is a perspective view of the connector having the band folded over;

FIG. 22 is a side view of different heating tape arrangements according to the present invention;

FIG. 23 is a side view of an arrangement for linking multiple heating tapes;

FIG. 24 is a perspective view of an arrangement for electrically connecting heating tape to feeding tape;

FIG. 25 is a perspective view of another arrangement for electrically connecting heating tape to feeding tape;

FIG. 26 is a perspective view of the connector with round-shaped posts;

FIG. 27 is a perspective view of the connector with teeth-like shaped posts;

FIG. 28 is a side view of additional heating tape arrangements;

FIG. 29 is a side view of an additional heating tape arrangement;

FIG. 30 is a side view of an additional heating tape arrangement;

FIGS. 31A and 31B are side views of additional heating tape arrangements;

FIG. 32 is a top view of an OEM connector for connecting the tapes with a current flow in a Z-direction;

FIG. 33 is a perspective view of the connector being encapsulated according to the present invention;

FIGS. 34A and 34 B are perspective views of additional heating tape connections;

FIG. 35 is a perspective view of an exemplary process of forming a heating tape in accordance with the present invention;

FIG. 36 is a perspective view of another exemplary heating tape arrangement in accordance with the present invention;

FIG. 37 is a sectional view of another exemplary heating tape arrangement in accordance with the present invention;

FIG. 38 is a perspective view of another exemplary heating tape arrangement in accordance with the present invention;

FIG. 39 is a perspective view of an exemplary connection according to an aspect of the present invention;

FIG. 39A is cut away perspective view of another exemplary connection according to an aspect of the present invention.

FIG. 40 is a top view of another exemplary heating tape structure according to an aspect of the present invention.

FIG. 40A is a top view of another exemplary heating tape structure according to an aspect of the present invention;

FIG. 40B is a top view of a heating tape with cutting lines to show how the tape can be cut for the embodiment of FIG. 40A.

FIG. 41 illustrates a process of forming a heating tape structure such as that shown in FIG. 40.

FIGS. 42-43 also illustrate processes, which can assist in forming a heating tape structure such as that shown in FIG. 40.

### DETAILED DESCRIPTION

### Improved Heating Tape

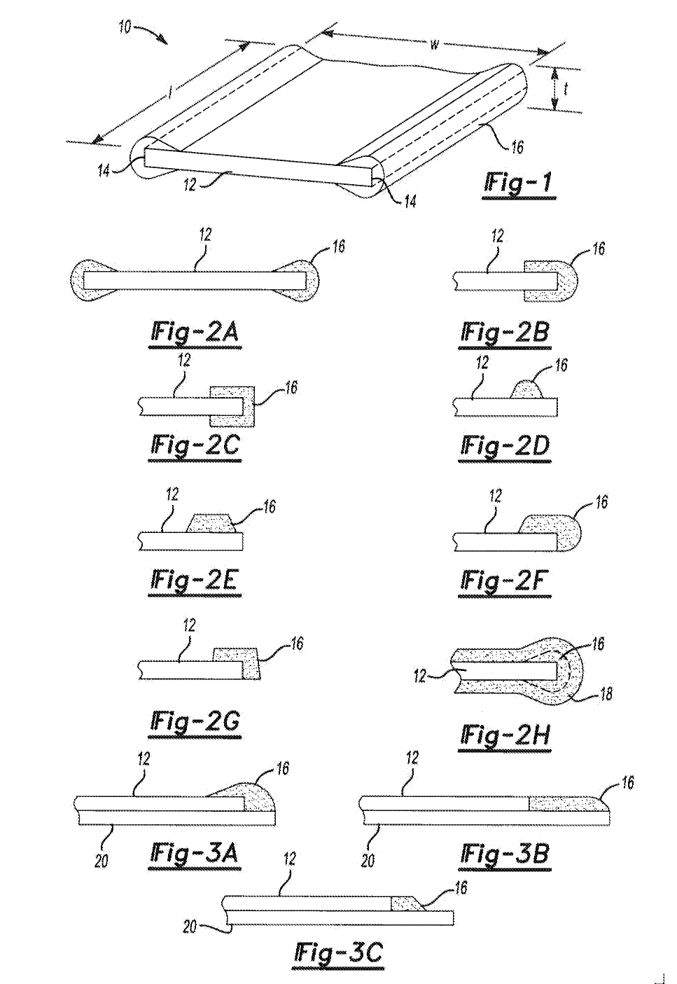

FIG. 1 generally depicts the major components of an exemplary heating tape 10 according to the present invention. The heating tape 10 is generally comprised of a base film 12 having edges 14 arranged at two opposite sides of the base film 12 and conductive strips 16 formed on the base film 12. The conductive strips 16 are arranged to receive electrical current from feeding terminals connected to a power source (e.g. 12 volt battery) to produce an electric potential between the conductive strips 16, and heating up the base film 12 accordingly.

The heating tape 10 is defined by a length (l), width (w), and thickness (t), where the heating tape 10 is formed to have a length that is at least twice, more typically at least 8 times and even more typically at least 15 times any dimension of the tape perpendicular to the length. A designer can manufacture the heating tape 10 in a combination of sizes to fit a particular need. However, there may be limitations on the length of the tape 10. Specifically, the heating ability of the heating tape 10 is a function of the length of the tape 10 or the distance a portion of the tape is from the terminals feeding current to the tape. Consequently, the heating ability of the portion of the tape 10 furthest from the feeding terminals will be reduced if the length (l) of the tape 10 is too large. The designer can account for this reduction by placing additional feeding terminals at different locations of the tape 10 and/or by shortening the length of the tape 10. Other ways of maximizing the heating ability of the tape 10 include, but are not limited to, changing the conductive material of the tape 10 or interconnecting a number of heating tapes 10 together, which will further be discussed in more detail below. Shortening the length of the tape 10 can be avoided by powering both ends of the tape 10.

In applications such as for automotive seats, it can be desirable for the tape to have dimensions within particular ranges. The length of the tape 10 and/or film 12 is typically at least about 4 cm, more typically at least about 12 cm and still more typically at least about 20 cm but is typically less than about 400 cm, more typically less than about 100 cm and still more typically less than about 50 cm. It should be understood, however, that larger or smaller lengths are also considered within the scope of the present invention unless otherwise specifically stated. The width of the tape 10 and/or film 12 is typically at least about 0.5 cm, more typically at least about 1.5 cm and still more typically at least about 3 cm but is typically less than about 40 cm, more typically less than about 10 cm and still more typically less than about 5 cm. It should be understood, however, that larger or smaller widths are also considered within the scope of the present invention unless otherwise specifically stated. The thickness of the tape 10 and/or film 12 is typically at least about 0.01 microns, more typically at least about 0.12 microns and still more typically at least about 2.0 microns but is typically less than about 2 mm, more typically less than about 100 microns and still more typically less than about 10 microns. It should be understood, however, that larger or smaller lengths are also considered within the scope of the present invention unless otherwise specifically stated.

In the embodiments shown, the length of the tape and film is the dimension that is substantially parallel to and/or coextensive with the conductive strips and the width is transverse and/or substantially perpendicular to these strips. It is contemplated, however, that the dimension that is substantially parallel to and/or coextensive with the strips may be smaller than the dimension that is substantially perpendicular to and/or transverse to the strips (i.e., the direction of conductivity or current flow through the strips. Thus, the ratios between these dimensions could be anywhere between 1:50 and 50:1.

The heating tape 10 is typically shaped as a strip or ribbon. Such a configuration provides for a heating tape 10 that can be produced in large rolls and can be easily assembled and/or manufactured (e.g. cut to form the pieces or tapes to desired length). Moreover, such configuration allows the heating tape 10 to be easily woven into a woven structure or any woven or non-woven perforated carrier of a seat. The tape 10 can have a longitudinal deflection and an angular deflection that is compensated by extending the length (l) of the tape 10 so that it is greater than the length of the surface of the object the tape 10 is placed on. The tape 10 may also be routed in a waved or zigzag pattern or be corrugated to enhance its longitudinal expansion ability. Moreover, a designer can easily incorporate the tape 10 to a vast number of applications on an “as needed” basis because of its strip-like form. The tape 10 can be placed over, under, inside or a combination of locations of highly complicated three-dimensional surfaces, which for exemplary purposes is a vehicle seat.

Still referring to FIG. 1, the base film 12 of the heating tape 10 is preferably made of a thinly flat conductive material designed to heat up when receiving electrical current from the conductive strips 16. Various different types of conductive materials can be used to make up the base film 12. Such materials include, but are not limited to metals (e.g. copper, nickel), conductive polymers or a combination thereof. It is contemplated that the base film 12 can be made from Positive Thermal Coefficient (PTC), Negative Thermal Coefficient (NTC) and/or Constant Thermal Coefficient (CTC) heating materials that are capable of reaching a predetermined temperature and have moderate flexibility. It is also contemplated that the base film 12 includes a small elongation coefficient of no more than 10%. In a preferred embodiment, the base film is formed of a PTC polymer.

In a preferred configuration, the conductive strips 16 are located substantially along the edges 14 of the base film 12 and substantially extend along the entire length (l) of base film 12. This arrangement allows electric current to flow through the base film 12. Optionally, the conductive strips 16 may be located anywhere on the top surface, bottom surface, side surface or on a combination of surfaces on the base film 12. The conductive strips 16 may also offset from one or both edges 14 of the base film 12. The conductive strips 16 may be in a variety of configurations on the base film 12 (e.g., rectangular, square, circular, polygonal or otherwise). FIGS. 2(a)-(g) are cross-sectional views of one end of the heating tape 10 showing a few of the many ways to arrange the conductive strips 16 on the base film 12. As illustrated, the conductive strips 16 may be formed in a variety of shapes having different sizes and located at different surfaces of the base film 12.

Preferably, the conductive strips 16 formed on the base film 12 are made of a material having higher conductivity than the material of the base film 12. This allows the conductive strips 16 to produce a desired electric potential on the base film 12. Some preferred materials for the material of the conductive strips 16 are conductive compounds, metallic fibers or synthetic fibers with metallic coating. Other suitable materials can be found in U.S. Pat. Nos. 3,974,107, 4,331,714, 4,407,674, 4,548,879, 5,736,261, 5,658,499, 5,492,653, and 5,147,453 herein incorporated by reference. The distance placed between the conductive strips 16 also influences the heating ability of the base film 12. The heating area of the base film 12 lies between the conductive strips 16. As such, the larger the distance between the conductive strips 16, the larger the heating area of the base film 12. A large heating area may require more power from the current source and/or additional feeding terminals in order to bring the base film 12 to a desired temperature. The distance placed between the conductive strips 16 could be varied to provide various power levels produced on the base film 12. Other methods of varying the power levels of the tape 10 include changing the distance between conductive strips 16, equipping the tape 10 with a current feeding network that is capable of energizing several points along the tape 10, changing the conductive material of the film 12, changing the base film thickness or a combination thereof.

In one preferred configuration, the edges 14 of the base film 12 are coated with the conductive material to form conductive strips 16 using various coating processes. These processes include but are not limited to bonding, laminating, spraying, off-set (roller) printing, screen and other kinds of printing, over-molding, co-extrusion or other known processes. Advantageously, the coating process to form conductive strips 16 on the base film 12 can be done easily through very little manipulation on the base film 12.

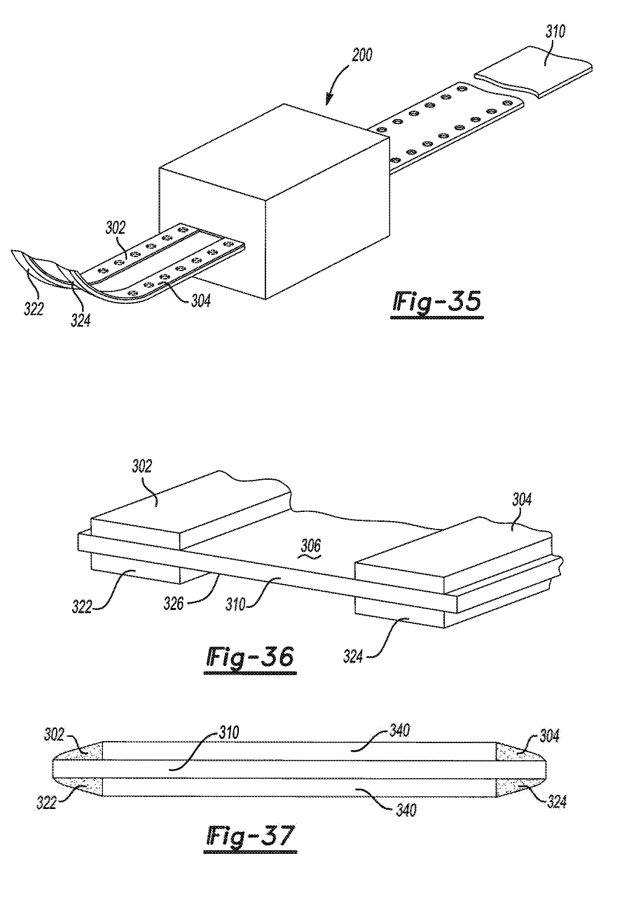

In one example, with reference to FIG. 35, the base film 12 is formed as a long strip (or ribbon) and is routed through an opening of an automated track system 200 such as one with a conveyor belt, rollers or the like for moving the base film 12 along one directional path, having stationary or moving dispensers (e.g., nozzles or rollers). The dispensers spray, pour, roll or otherwise dispense one or more layers of conductive material on or adjacent edges 14 as the film 12 is moved down or along the system.

Once the conductive strips are dispensed, and referring back to FIGS. 1-5 those strips or layers of conductive are hardened or dried using conventional drying methods such as heating, or is dried immediately after contact, depending on the material being used. In some cases, the edges 14 may require several layers of conductive material to form strips 16 of a desired thickness. In this case, several coating stages with intermediate delays are implemented in the coating process for drying or polymerization after each layer is coated. This may provide for more even strips 16 and help prevent cracks from easily forming on the strips 16 caused by drying conductive compound and shrinkage. In another example, the conductive material is spread onto the edges 14 of the base film 12 like paste and dried accordingly. In yet another example, the conductive strips 16 are over-molded together with the base film 12.

Generally, as the tape is formed in a continuous manner by the automated system or thereafter, the tape may be divided (e.g., cut) into tapes of desired lengths. This cutting may occur after formation of the tape, after drying of the conductive material or after option protective coating is applied or otherwise.

### Heating Tape with Adhesion Layer

In one embodiment, as seen in FIG. 2(h), an adhesion layer 18 is applied to the heating tape 10 for assisting in securely attaching the heating tape 10 to any portion of the seat. Specifically, the adhesion layer 18 may be applied on and cover any surface of the base film 12 and/or the conductive strips 16 in full or in part. The adhesive layer is made of a material that may include polyamides, polyesters, elastomers, expoxies, urethanes, olefin polymers or a combination thereof. It is also contemplated that the adhesive layer can be chosen to provide integrity to the tape structure. The adhesion layer 18 may be applied continuously or non-continuously to the heating tape 10 as droplets, points, spots, strips or the like using similar coating processes as discussed above. The adhesion layer may also be applied on the surfaces of the heating tape 10 in a pattern, such as, for example, a zigzag pattern. Preferably, the exterior surfaces of the base film 12 and conductive strips 16 are coated (painted, enameled, sprayed, overmolded) with the adhesion layer 18. The adhesion layer 18 may also function to electrically insulate the heating tape 10 from any undesired connections. A release layer (e.g., release paper) may be used to cover the adhesive layer until the heating tape is to be applied to a substrate such a foam cushion or other portion of vehicle seat. Thereafter, the release layer can be removed and the tape structure adhered to the substrate.

Heating Tape with Backing Layer

In another embodiment, a backing layer 20 is attached to the heating tape 10 for providing support to the base film 12 and the conductive strips 16, which helps to improve the overall mechanical properties of the heating tape 10. The backing layer 20 is made of a dielectric material (e.g. polymer) that operates to dissipate static electricity as well as provide support and protection to the tape 10. As illustrated in FIGS. 3(a)-(c), the backing layer 20 may be attached to any portion and on any surface of the base film 12 and the conductive strips 16 in full or in part. The backing layer 20 may also have a more narrow width than that of the base film 12 if suitable for the desired application. It should be understood that the term “dielectric material” used throughout the description is not limited to materials that are non-conductive; rather it is contemplated that other materials can be used to purge electricity or perform other functions.

In a preferred configuration, edges of the backing layer 20 are aligned with or adjacent to the edges 14 of the base film 12, and/or are aligned with the outer perimeter of the conductive strips 16 that may extend over the edges 14 of the film 12. The backing layer 20 may also extend beyond the base film 12 and the conductive strips 16. Extending the backing layer 20 beyond the base film 12 and conductive strips 16 can help to better protect the edges 14 and the conductive strips 16 of the base film 12 against mechanical forces.

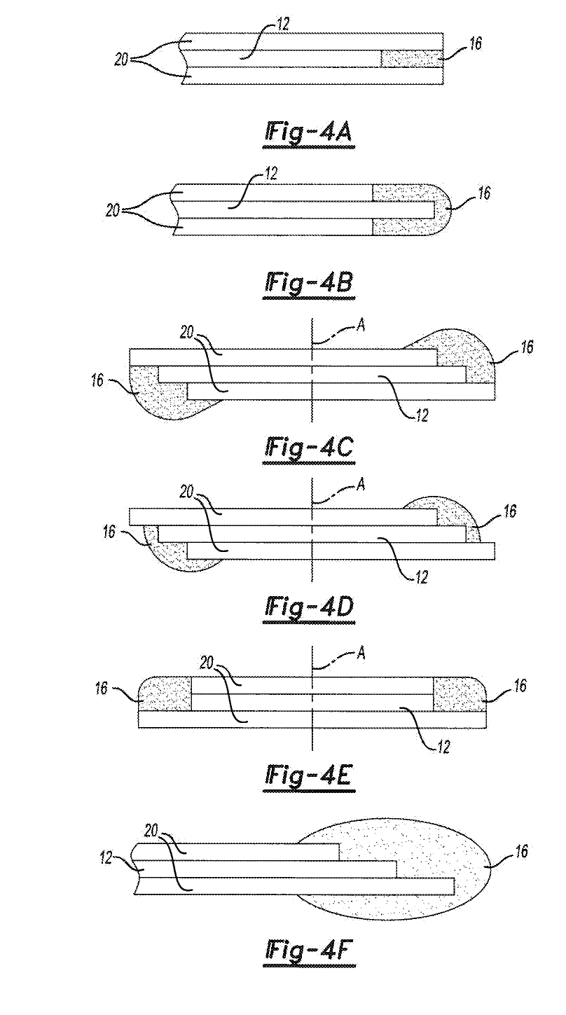

With reference to FIGS. 4(a)-4(f), the heating tape 10 can include more than one backing layer 20. For example, one backing layer 20 can be disposed on a top or first surface of the base film 12 and a second backing layer 20 can be disposed on a second or bottom surface of the base film 12. Each backing layer 20 can cover a part of or the entire top or bottom surface of the base film 12. Having a backing layer 20 supporting or covering the top as well as the bottom surface of the base film 12 provides for additional protection to the edges 14 of the film 12 against mechanical forces. There are many ways to align each backing layer 20 with respect to the base film 12 and the conductive strips 16 of the tape 10. FIGS. 4(a)-(f) show a few of the many different ways to arrange each backing layer 20 to the heating tape 10. The tape 10 and the backing layers 20 may have mirrored symmetrical edges of any style, such as the one shown in FIG. 4(c), (d), and (e). As such, the electrical connection to the tape 10 will differ depending on the symmetry chosen for the tape 10.

Each backing layer 20 can be secured to the base film 12 before or after the conductive strips 16 are coated on the base film 12. The backing layer 20 can be attached or laminated to the base film 12, conductive strips or both 16 using various adhesives or welding technologies. Optionally, one surface of the backing layer 20 may include an adhesive component that bonds the backing layer 20 to the film 12 and strips 16. Each backing layer 20 can also be overmolded together with the base film 12 and conductive strips 16. FIGS. 22(a)-(d) illustrate several ways to arrange the backing layer 20 to the heating tape 10. Incorporating more than one backing layer 20 may create one or two seams 21 as shown in FIGS. 22(a), (b), and (d).

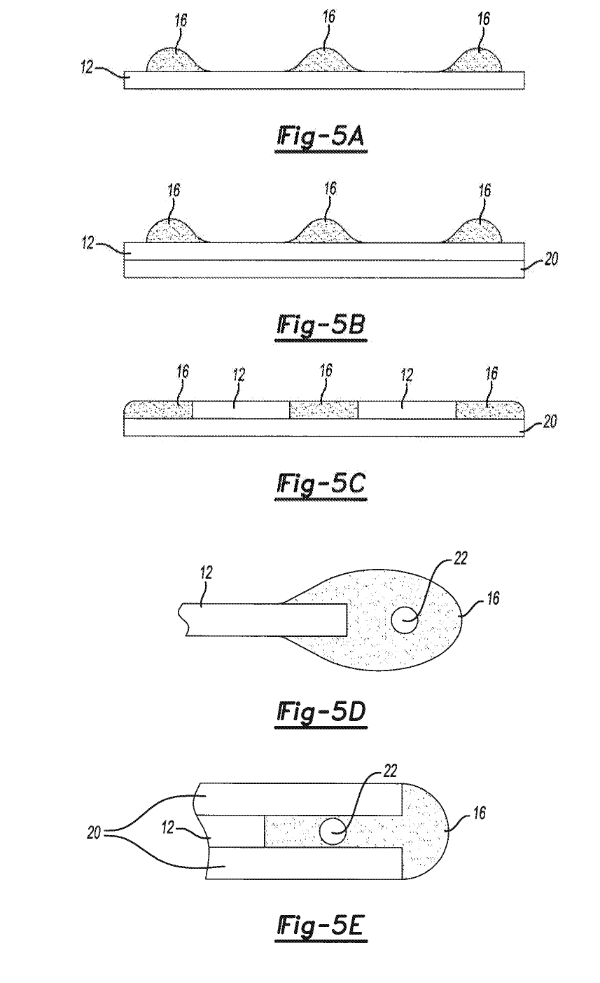

As shown in FIGS. 5(a)-(c), it is contemplated that more than two conductive strips 16 are formed on the base film 12. Specifically, in one configuration as seen in FIG. 5(a), three conductive strips 16 are coated on base film 12 forming two heating areas in between the conductive strips 16. In another configuration as seen in FIG. 5(b), three conductive strips 16 are formed on base film 12, where the base film 12 includes a backing layer 20 attached to the bottom surface of the base film 12. In yet another configuration as seen in FIG. 5(c), a backing layer 20 is disposed in between each of the separated conductive strips 16 and attached on portions of the top surface of the base film 12. These described configurations illustrate a few of the many different arrangements a designer can employ to make a heating tape 10 for a specific application. It should be understood that there could be more than three conductive strips 16 formed on the base film 12 and each can be arranged in a combination of ways.

It is contemplate that the base film and the backing layer of the present invention may be formed of a variety of materials. Preferably, they are formed of polymeric films (e.g., polyimide films). It is also preferable for the base film to include conductive material dispersed in the film while the backing layer is typically dielectric. The conductive strips are typically formed of a conductive polymeric material (e.g., conductive polymer ink) that is preferably suitable for layering upon the base film.

### Heating Tape with Filaments

It is also contemplated that a filament 22 can be imbedded or impregnated into the conductive strips 16 as seen in FIGS. 5(d) and 5(e). The filament 22 operates to reinforce the conductive strips 16, which in turn assists in protecting the edges 14 of the base film 12 against mechanical forces. The filament 22 is generally made from a polymer, carbon, metal, inorganic glass, basalt, or a combination thereof in varying proportions. The filament 22 may also include more than one fiber made of one or a combination of materials listed above. For example, the filament 22 can include two fibers, one made of a highly conductive material (e.g. metal) and the other made of a strengthening material (e.g. glass). Optionally, the fiber(s) of the filament 22 may include a casing (not shown) made of a conductive or non-conductive material to help reinforce each fiber. The casing may be overmolded, coated, painted, plated, or deposited in a vacuum over the fiber(s) of the filament 22. The filament 22 may take the form of any shape (e.g. circular, square, polygonal, etc.). The fibers of the filament 22 may also be braided in any style. It should be understood that more than one filament 22 could be placed within one or both of the conductive strips 16. It should further be understood that the filament 22 could have either a smooth or uneven surface.

Heating Tape Structure

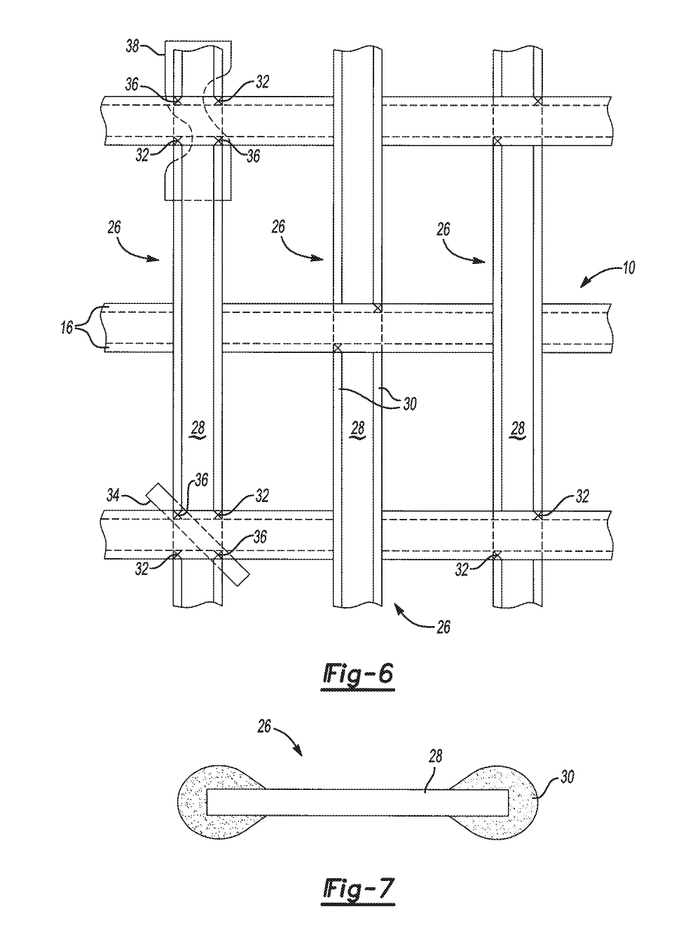

FIG. 6 illustrates a flexible heating tape structure 24 according to the present invention. The heating tape structure 24 generally comprises a number of heating tapes 10 and feeding tapes 26 electrically connected together. As illustrated in FIG. 7, the feeding tape 26 of the present invention generally comprises a substantially flat sheet 28 made of a non-conductive polymer (e.g. polyethylene, nylon, etc.). Each feeding tape 26 includes busses 30 made of a conductive material (e.g. metal or conductive compound) formed mutually opposite each of its ends or coextensive to each of its edges. Each feeding tape 26 is used to feed electrical current to one or more heating tapes 10 and/or electrically connect each heating tape 10 to one another. Each feeding tape 26 provides for additional flexibility to the structure 24 due to its elastic characteristics. Both proposed heating tapes 10 and feeding tapes 26 are similar to flat cables with metal foil conductors but differ in material and technology. The conductive strips 16 of each heating tape 10 and busses 30 of each feeding tape 26 can be printed, molded, painted, poured, or sprayed onto their base.

In one embodiment, two or more heating tapes 10 are contacted (e.g. woven together) with two or more feeding tapes 26 forming a pattern as shown back in FIG. 6. The pattern can be of any form, such as, for example, a criss-cross pattern. Preferably, the feeding tapes 26 are spaced apart to contact the heating tapes 10 at different strategic locations. Preferably, each heating tape 10 is corrugated to longitudinally expand with the feeding tape 26, although not required unless otherwise stated. The heating structure 24 can be easily incorporated into a vehicle seat, and more specifically to the cushion or trim of the seat. Specifically, the configuration provides the heating structure 24 the capability to flex or deform to the movements of a user on the seat. Such a flexible configuration can help prevent cracking along the edges of the base film 12 of each heating tape 10, thereby maintaining the integrity of the heating capabilities of each heating tape 10. In an alternative embodiment, a number of corrugated heating tapes 10 are contacted together (e.g. woven together) to form structure 24, eliminating the need for feeding tape 26. In this alternate embodiment, at least one heating tape 10 is directly connected to a power source to heat up the structure 24. The structure 24 can be formed of a number of interconnected heating tapes 10 or a combination of heating tapes 10 and feeding tapes 26. However, the description below will only discuss a structure with both heating tapes 10 and feeding tapes 26 connected together.

The heating structure 24 further includes connection points 32. The connection points 32 are defined where the heating tape 10 intersects with the feeding tape 26, and more particularly, where the strips 16 of the heating tape 10 electrically connect to the busses 30 of feeding tape 26. The heating structure 24 may also include a film mask 34 made of a dielectric material to help prevent any undesirable connections (e.g., electrical connections or shorts) between the heating tapes 10 and feeding tapes 26, which in this example are connection points 36. The film mask 34 can be inserted between the heating tape 10 and feeding tape 26 in order to cover the undesirable connection points 36. The film mask 34 can take the form of any shape (e.g. rectangle). Another film mask shape is represented as film mask 38. These masks 34, 38 could be inserted between the tapes prior to welding or soldering connection points 32.

The proposed feeding tape 26 may be used for heating as well. Each feeding tape 26 may be powered in parallel or in series. The feeding tape 26 may be directly connected to a power source for powering up each of heating tapes 10 in the structure 24. Alternatively, each heating tape 10 can be directly connected to a power source as previously described, eliminating the need for feeding tapes 26. Another alternative would be to connect a power source to both the heating tapes 10 and feeding tapes 26 if both tapes are used. Having more power sources connected to the heating structure 24 will help maximize the heating ability of the structure 24. The design of heating structure 24 and the powering up arrangement will often depend on the application. Some of the considerations include the amount of surface to heat, the thickness of the surface, the shape of the surface, the number of heating tapes used, etc. It should be understood that other conductors could be used as heat emitting elements for heating up the heating tape 10 and can be applied to different points along the strips 16 or tape structure 24.

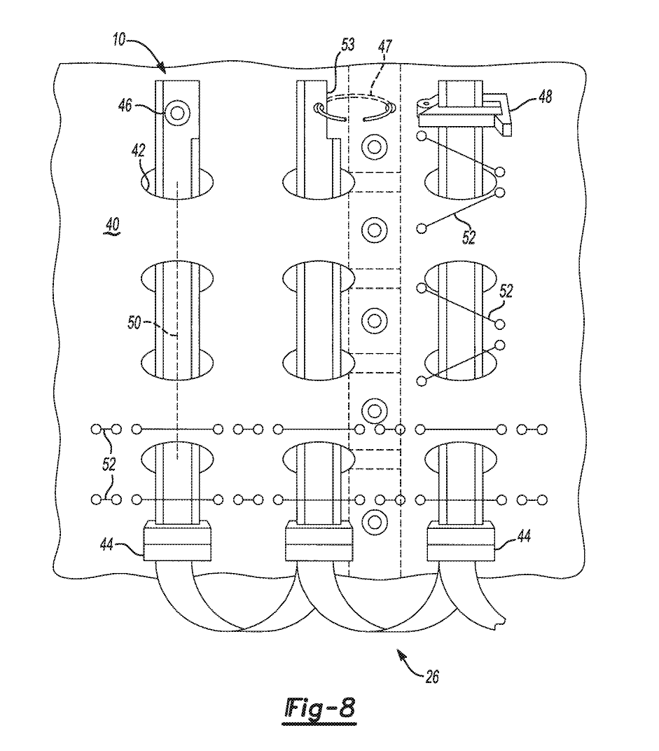

FIG. 8 illustrates another example of a heating structure 24 according to the present invention. In one embodiment, heating tape 10 is incorporated into an automotive seatback by weaving the heating tape 10 into a carrier 40 of the seatback. The carrier 40 could be, for example, the cushion of the seatback or a separate carrier that is made of a substrate (e.g. a polymeric film, foam, woven or unwoven textile) that includes openings 42. In this example, the heating tape 10 is fed or woven through the openings 42 of the carrier 40. Once the heating tape 10 is fed through the openings 42, one end of each heating tape 10 is securely attached to the carrier 40 in order to prevent the heating tape 10 from pulling out of the carrier 40. The opposite end of the heating tape 10 is electrically connected to the feeding tape 26 via a connector 44. The connectors 44 will further be discussed below in more detail. The feeding tape 26 is routed through like ribbon across each connector 44 to electrically connect each heating tape 10 together and/or to a power or electrical energy source. Having such a configuration may only require one power source to be electrically connected to one feeding tape 26 to heat up the entire structure 24. Other methods of incorporating heating tape to a seatback include but are not limited to impregnating the heating tape 10 onto an air permeable structure (e.g. spacer material), attaching the heating tape 10 directly on a portion of the seatback, and over molding the heating tape 10 onto a portion of the seatback.

FIG. 8 shows three of the many ways to attach one end of the heating tape 10 to the carrier 40. One end of the heating tape 10 can be attached to the carrier 40 by a fastener, such as a rivet 46, a staple 47, or by a clip 48. Alternatively, the heating tape 10 can be sewn through along the symmetrical line 50 of the heating tape 10 in order to hold the heating tape 10 in close contact with the carrier 40. Stitches 52 can also be sewn over the heating tape 10 or the carrier 40 to more securely attach the heating tape 10 to the carrier 40. It should be understood that a combination of one or more of the fastening devices described above or ones that are not mentioned could be used to securely attach the heating tape 10 to the carrier 40.

Optionally, cuts 53 can be placed on the heating tape 10 to remove any undesirable piece of the conductive strips 16 to help reduce heating locally. Placing cuts 53 can also help prevent any current shortage near any connection spot or undesirable connections. See for example the cut shape 53 of FIG. 14.

### Connectors

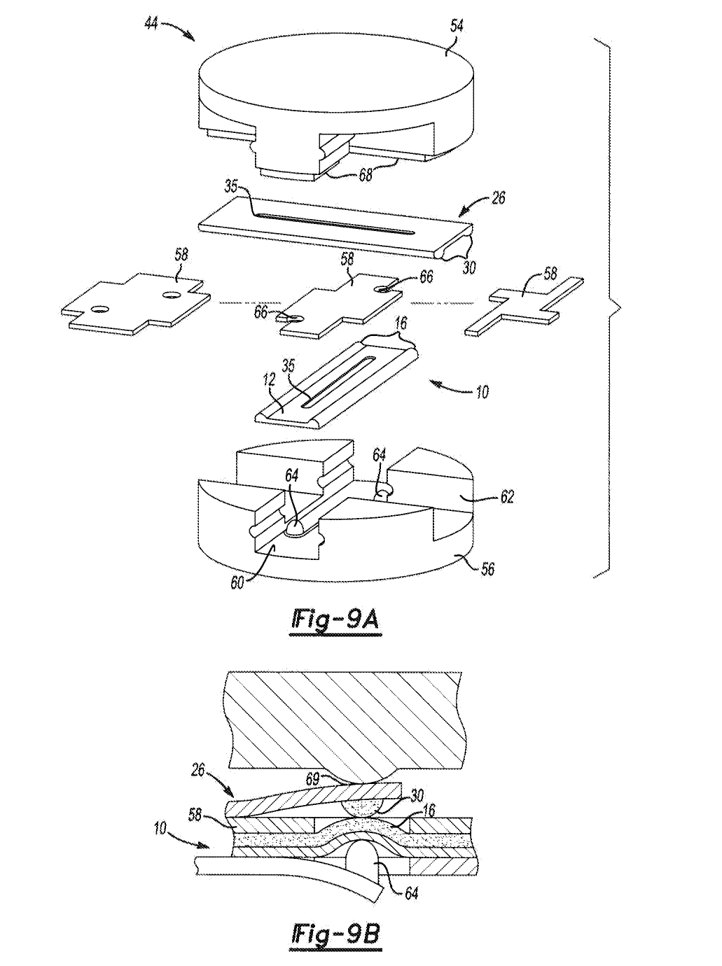

The connector 44 is used to connect the heating tape 10 to the feeding tape 26. Alternatively, it can be used to connect one heating tape 10 to another heating tape 10 or one feeding tape 26 to another feeding tape 26. For exemplary purposes and as illustrated in FIG. 9a, connector 44 electrically connects one heating tape 10 to one feeding tape 26. The connector 44 generally comprises a top base 54 and a bottom base 56 both made preferably of a dielectric material (e.g. plastic) with a high friction coefficient, and a film mask 58 made of a similar material to prevent any undesirable connections. The bottom base 56 includes two intersecting channels 60, 62 respectively. One channel is preferably cut deeper into the bottom base 56 than the other channel in order to accommodate the thickness of the heating tape 10. The angles between the channels 60, 62 preferably measure approximately 90 degrees. However, the channels 60, 62 may be oriented in a variety of angles for specific applications or heater patterns. Two springy bulges (vertexes, mounts, springs) 64 are located on the bottom base 56 in generally the central zone in which the conductive strips 16 of the heating tape 10 align. The springy bulges are better illustrated in FIG. 9b. The springy bulges 64 are located diagonally from one another within the central zone as better illustrated in FIG. 10.

In operation, the heating tape 10 is placed in the intersecting channel 60, which preferably is deeper than channel 62. The heating tape 10 is oriented in a manner so that the conductive strips 16 are exposed and are facing towards the top base 54. The film mask 58 is then placed over the heating tape 10. The film mask 58 may be of any shape (e.g. puzzle-like) providing openings 66 to expose desirable portions of the conductive strips 16. The feeding tape 26 is laid into the channel 62 and oriented so that the conductive busses 30 of the feeding tape 26 are exposed and are facing towards the bottom base 56. Then, the top base 54 is lowered and mated together with the bottom base 56. The placement of the heating tape 10 and the feeding tape 26 into channels 60, 62 respectively and the design of the film mask 58 allow the busses 30 of the feeding tape 26 to align with the strips 16 of the heating tape 10 and electrically connect at connection points marked “x”.

The top base 54 is shaped so that it corresponds with the shape of the bottom base 56. When the top base 54 and bottom base 56 are mated or crimped together, the bases 54, 56 force the springy bulges 64 to push a portion of the conductive strips 16 of the heating tape 10 through the film mask 58 and connect them to a portion of the conductive busses 30 of the feeding tape 26 as illustrated in FIG. 9B. The points of connection are marked “x”. The springy bulges 64 are pre-loaded so that once the top base 54 is mated with the bottom base 56, the heating tape 10 and the feeding tape 26 remain electrically connected until the bases 54, 56 are pulled apart. The springy bulges 64 may also be placed on the top base 54 of the connector 44 or both.

The top base 54 and/or the bottom base 56 may also include spring pads 68 to help compress the peripheral zones of each tape (not over bulges 64). Preferably, four spring pads 68 are placed on each end of the top base 54 and configured to fit within the channels 60, 62 of the bottom base 56. The spring pads 68 are positioned to only compress the peripheral zones of the heating tape 10 and feeding tape 26 to assure that the conductive strips 16 of the heating tape 10 are electrically connected to the conductive busses 30 of the feeding tape 26. The spring pads 68 help stabilize and make the electrical connection between the tapes 10, 26 respectively more durable. It should be understood that the spring pads 68 could be used together with the bulges 64 or without depending on the designer's preference. Optionally, a mount 69 may be placed on the top base 54, opposite the springy bulges 64, to help equalize the tapes 10, 32 deflection towards each other.

The heating tape 10 and the feeding tape 26 can heat up within the connector 44. However, if heat is not desired within the connector 44, a longitudinal cut 35 can be made on the heating tape 10 and/or feeding tape 26 in the connection area.

FIG. 10 illustrates another embodiment of the connector 44. The connector 44 in this embodiment is similar to the one shown in FIG. 9. However, the top base 54, bottom base 56, and film mask 58 each have a tail 72, 74, 76 respectively. Each tail 72, 74, 76 is connected together at their respective ends by a clip 78 to facilitate easy installation. Other fasteners or adhesive could be used to connect each tail 72, 74, 76.

FIG. 11 illustrates yet another embodiment of the connector 44. The connector 44 in this embodiment includes a hinge assembly 80. The hinge assembly or mask 58 includes a window 82. A hinge joint 84 is assembled inside the window 82. The mask in the window 82 further includes teeth 86 for receiving and centering the mask 58 between the top base 54 and bottom base 56. The hinge assembly 80 allows the top base 54 and bottom base 56 to move about the hinge joint 84. The joint 84 design may be configured in various arrangements to help align the mask 58, top base 54 and bottom base 56 for easy assembly.

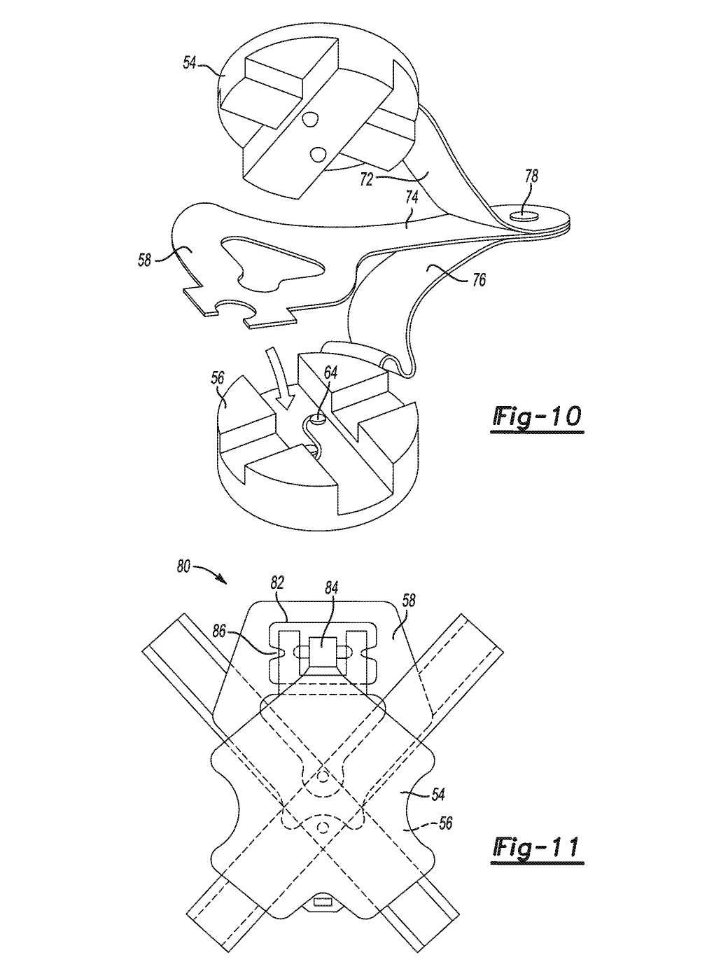

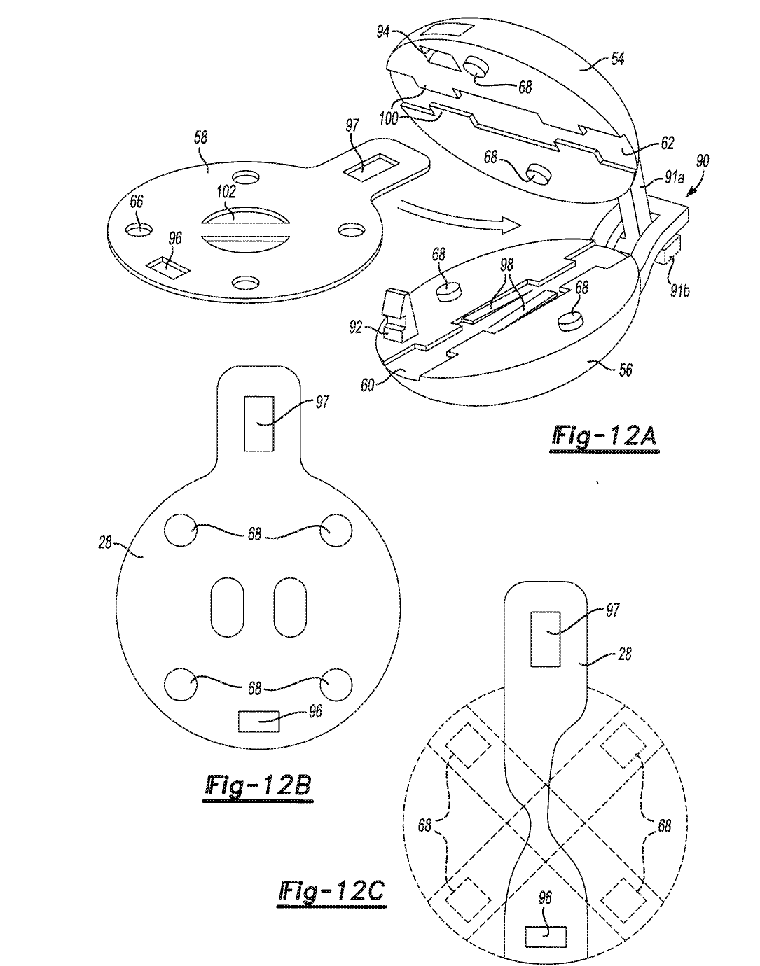

FIG. 12a illustrates an additional embodiment of the connector 44. The connector 44 in this embodiment includes a joint assembly 90 with a top stem and bottom stem 91a, 91b respectively. The joint assembly 90 enables the top base 54 and bottom base 56 to move in an open and closed position. The connector 44 may also include a clasp 92 on the bottom base 56 to assist in attaching the top base 54 to the bottom base 56 and aid in positioning the film mask 58 between the top base 54 and the bottom base 56. The top base 54 includes a cut out 94 for receiving the clasp 92. The film mask 58 also has a corresponding opening 96 for receiving the clasp 92. The clasp 92, cut out 94, and opening 96 are aligned with one another. As such, when the top base 54 and bottom base 56 are mated together, the clasp 92 goes through the cut out 94 and into opening 96. As a result, the film mask 58 is firmly positioned between the top base 54 and bottom base 56 which are securely attached to each other by the clasp 92. Optionally, an opening 97 can be cut out from the film mask 58 in order for the film mask 58 to be worn by the top stem 91a of the hinge assembly 90 to aid in positioning the film mask between the two bases 54, 56. The spring pads 68 in this embodiment are attached to the top base 54 and the bottom base 56 of connector 44. Specifically, two spring pads 68 are attached to the top base 54 and two spring pads 68 are attached to the bottom base 56. The spring pads 68 on the top base 54 are positioned on opposite sides of channel 62. Similarly, spring pads 68 on the bottom base 56 are positioned on opposite sides of channel 60. Corresponding openings 66 are located on the film mask 58 to receive the spring pads 68. The spring pads 68 compress the heating tape 10 and feeding tape 26 when the top base 54 and bottom base 56 are mated. Additional positioning features include leaf-like springs 98 and tabs 100. The leaf-style springs 98 can be located on either the top base 54 or bottom base 56 of the connector 44. For exemplary purposes only, FIG. 12a illustrates two leaf-style springs 98 located in between the channel 60 of the bottom base 56. The two springs 98 are positioned side-by-side, aligning each spring 98 to one of the conductor strips 16 of the heating tape 10. In operation, the connector 44 is placed in a closed position thereby pushing the springs 98 against the conductive strips 16. The force placed on the conductive strip 16 by the springs 98 pushes points of the conductive strips 16 through two corresponding openings 102 on the film mask 58. Once those points of the conductive strips 16 go through openings 102, those points of the strips 16 contact with corresponding points of the busses 30 of the feeding tape 26 located on the top base 54 of the connector 44. This electrically connects the heating tape 10 to the feeding tape 26. The heating tape 10 and feeding tape 26 can be electrically connected together at different points by varying the configuration of the film mask 58. FIGS. 12b and 12c show two of these possible configurations of the film mask 58.

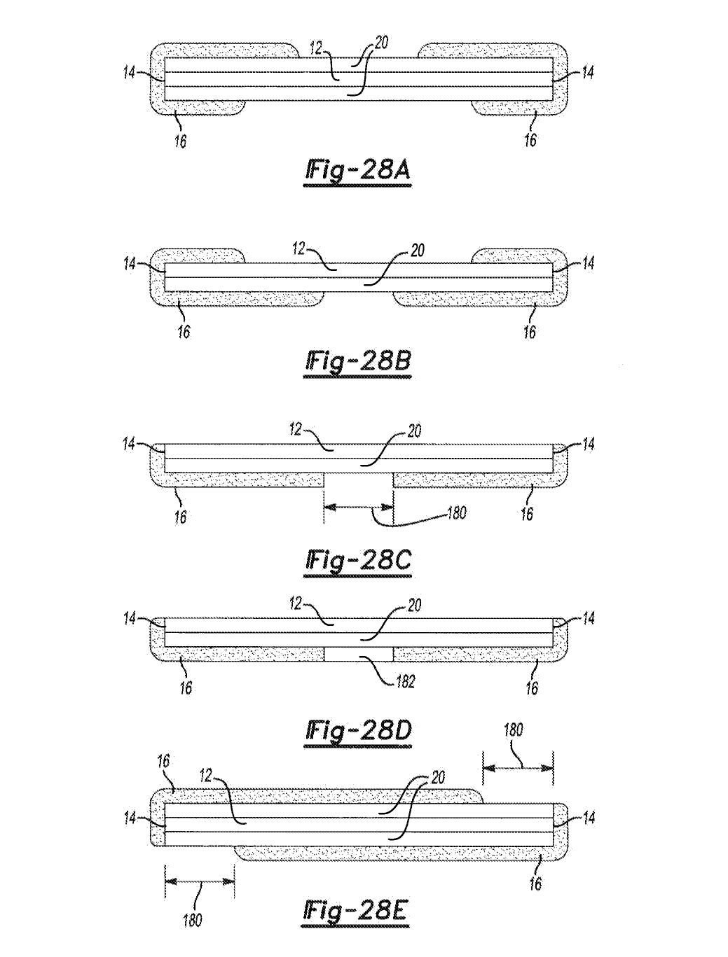

With respect to the tabs 100, the tabs 100 are formed on the top base 54 and bottom base 56 of the connector 44 and can be of any shape (e.g. conical-tooth). Tabs 100 can be formed along the channels 60, 62. The tabs 100 are used to hold the heating tape 10 and feeding tape 26 in place in between their respective channel. There are a variety of ways to hold the tapes in place in between the channels 60, 62. FIG. 26 illustrates one alternative. In this exemplary figure, posts 110 are placed on a flat surface of the bottom base 56 of the connector 44 and more specifically, along the sides of the channel 60. The posts 110 are round in shape and include a lip 112 around their top edge. Indents (not shown) are provided on the opposite base, which in this case, is the top base 54 for receiving the posts 110. The heating tape 10 is laid between the posts 110 and firmly secured by the lip 112 of the posts 110 and even more so when the posts 110 are pushed in their respective indents. FIG. 27 illustrates an optional shape for posts 110. The posts 110 in this example are square with a tooth 114 extending from their top edge. Other shapes may be implemented to help retain the tapes and are not limited to those previously discussed above.

It should be understood that one or more of the positioning features described above could be located on any portion of the top base 54 or bottom base 56 of the connector 44. It should further be understood that one or more of the positioning features described above could be molded together with the either the top base 54 or bottom base 56 or be made of a metal that is installed on the top base 54 or bottom base 56.

### OEM Style Connectors

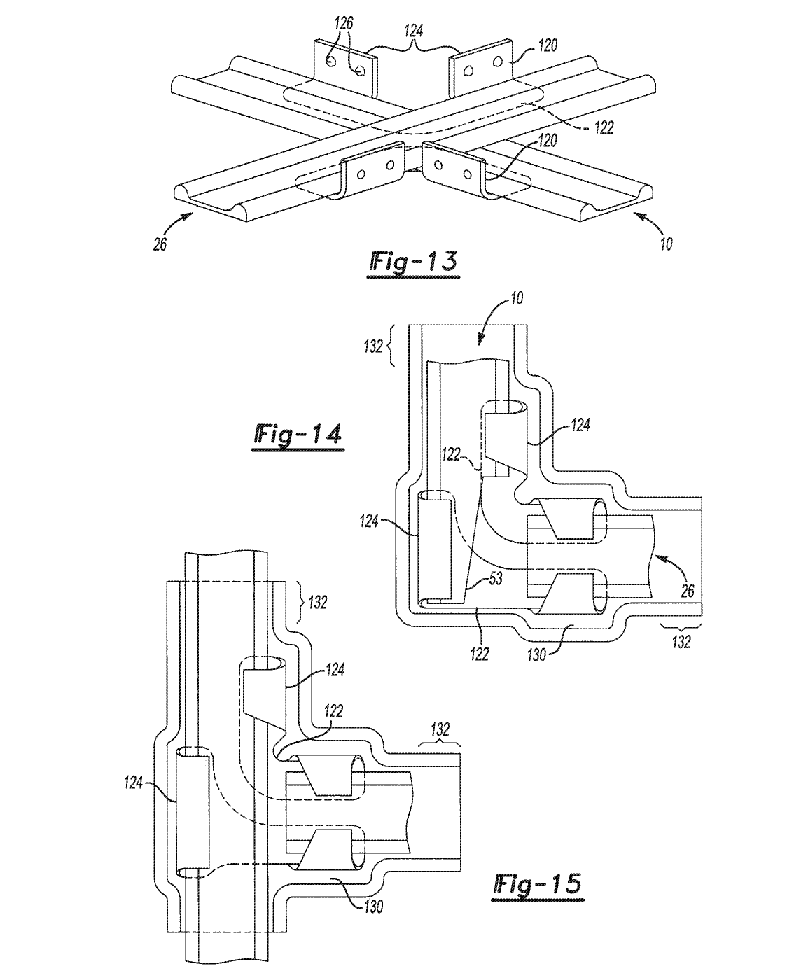

FIG. 13 illustrates another connector 120 according to the present invention for connecting heating tape 10 to feeding tape 26. The connector 120 generally includes bases 122 having an L-shape and at least two bendable metal tabs 124. One of the two bendable tabs 124 compresses down on one of the conductive strips 16 of heating tape 10 and the opposite tab 124 compresses down on one of the busses 30 of the feeding tape 26. The L-shaped bases 122 are oriented to contact both the heating tape 10 and the feeding tape 26. The heating tape 10 and the feeding tape 26 are generally intersected in an X-shaped fashion where the heating tape 10 faces the non-conductive backing of feeding tape 26. In such a configuration, at least two connectors 120 are needed to connect the heating tape 10 to the feeding tape 26. Specifically, one connector 120 is used to connect one of the two strips 16 on one end of the heating tape 10 to one of the two strips 30 on one end of the feeding tape 26. Accordingly, another connector 120 is used to connect the opposite strip 16 on the opposite end of the heating tape 10 to the opposite strip 30 of the opposite end of the feeding tape 26.

Optionally, the connector 120 may include teeth 126. The teeth 126 are used to penetrate through any insulation or adhesive that may be directly applied to the strips 16 or busses 30. The teeth 126 may be formed on the L-shaped base 122, the bendable tabs 124 or a combination of both.

FIGS. 14 and 15 illustrate the tapes 10, 26 in an L-shaped or T-shaped intersection. The bases 122 in these arrangements are also L-shaped; however, they are oriented in a way to better attach the heating tape 10 and the feeding tape 26 together. The heating tape 10 and feeding tape 26 can be oriented in a variety of ways to satisfy any specific application.

The intersecting tapes 10, 26 and connector 120 may be supported by an enclosure 130 that is made of a dielectric material. The enclosure 130 may be installed or overmolded only around the intersecting tapes and the base 122 of each connector 120 or around the entire area of the connector 120 including the bendable tabs 124. The enclosure 130 may include extended sleeves 132 to restrict the angular movement of the tapes 10, 26 near the intersecting point.

Once the heating tape 10 and feeding tape 26 are in place within the enclosure 130 and the bendable tabs 124 are compressed against the strips 16 and busses 30, the enclosure 130 may be filled with a hardening potting substance, such as, an epoxy base compound or molten polymer. Alternatively, the enclosure 130 can be covered with a lid 134 as shown in FIG. 16. The lid 134 may be hinged to the enclosure 130 using a hinge assembly (not shown) or may be molded together with the enclosure 130. Optionally, the enclosure 130 and corresponding lid 134 may be coated with an insulating material.

### Foil Connector

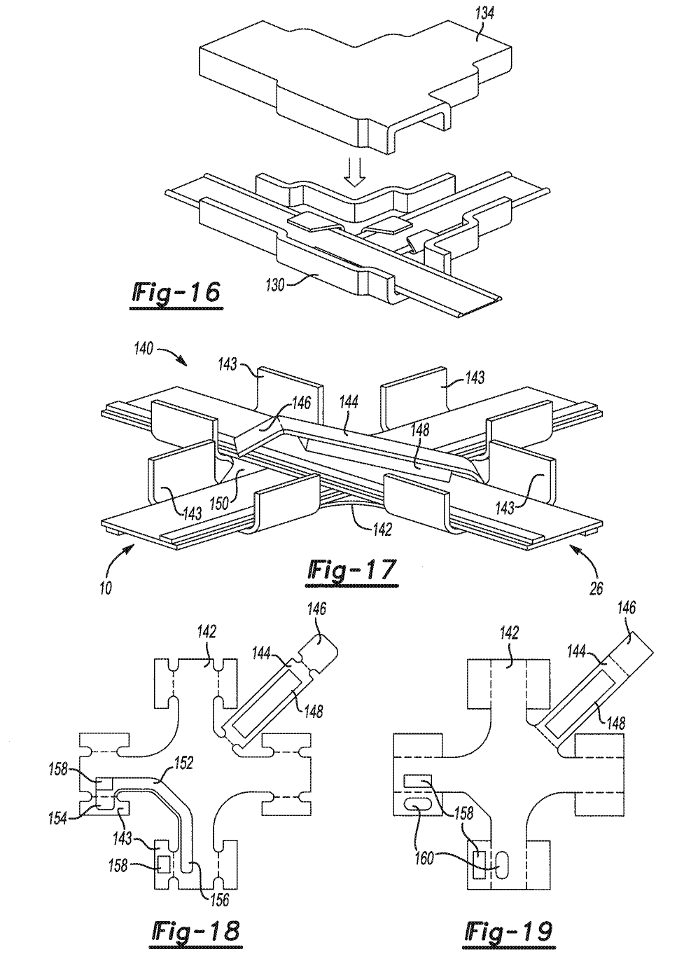

FIG. 17 illustrates yet another connector 140 according to the present invention for connecting heating tape 10 to feeding tape 26. The connector 140 generally includes a cross-shaped body 142 made of a deformable material, preferably a metal foil coated with a polymer or insulator. The cross-shaped body 142 includes terminal tabs 143 on each end of the cross-shaped body 142, a diagonal locking band 144 having a locking tab 146 and an elastic pad 148 attached to the one side of the band 144 that faces the tapes 10, 26 when folded down. The body 142 is used to hold the heating tape 10 and feeding tape 26 in an intersecting position. Preferably, the strips 16 of the heating tape 10 are located on opposite faces of the heating tape 10. The busses 30 of the feeding tape 26 must similarly be positioned. The strips 16 of the heating tape 10 and the busses 30 of the feeding tape 26 can be electrically connected in two ways using connector 140. Simply laying the feeding tape 26 on top of the heating tape 10 creates one connection point. Specifically, the strip 16 on the top face of the heating tape 10 electrically contacts the channel 30 on the bottom face of the feeding tape 26. Another connection point is created when the strip 16 on the bottom face of the heating tape 10 is electrically connected to the channel 30 on the top face of the feeding tape 26 by lowering the band 144, folding the tab 146 around the body 142, and locking the flap 146 to a bottom portion 150 of the body 142. When the band 144 is folded over, the elastic pad 148 compresses against the tapes creating a permanent pre-load on the two connection points marked as “x”. In one preferred embodiment, substantially the entirety of the surface of the foil connector is dielectrically coated except in locations where it is to contact specific conductive strips 16 or busses 30.

In one embodiment, a conductive conduit 152 is installed above the dielectric surface of connector 140 as shown in FIG. 18 to help electrically connect the heating tape 10 to the feeding tape 26. The conduit 152 can be of any shape, which for exemplary purposes is shown in FIG. 18 to have a boomerang or L-shape. The conduit 152 includes a conductive tab 154 covering one of the terminal tabs 143 for connecting and/or compressing the busses 30 of the feeding tape 26 to the conduit 152. As such, the feeding tape 26 energizes the conduit 152. A partition 156 is located under the heating tape 10, so when the terminal tab 143 is folded in, the second interconnection between the heating tape 10 and feeding tape 26 is created through the conduit 152. Optionally, elastic pads 158 may be installed near or on any of the terminal tabs 143, the body 142 of the connector 140, or both. These elastic pads 158 will maintain permanent preload force on the strips 16 and busses 30.

FIG. 19 illustrates another embodiment of connector 140. In this embodiment, the heating tape 10 and feeding tape 26 are electrically connected through the body 142 of the connector 140. The electrically insulated conductive deformable body 142 has two exposed metal spots 160 that face the electrically connected strips 16 and busses 30. Elastic pads 158 may also be applied in this embodiment to maintain the preloaded force on the strips 16 and the busses 30.

FIG. 20 illustrates yet another embodiment of connector 140. In this embodiment, protrusions 162 are introduced to help in positioning the tapes together prior to folding down the terminal tabs 143 of the body 142 of the connector 140. The protrusions 162 are generally mounts or bumps that are preferably molded over the connector 140 insulating coating. Alternatively, the protrusions 162 may be a separate component that is attached to the generally insulated body 142 of the connector 140.

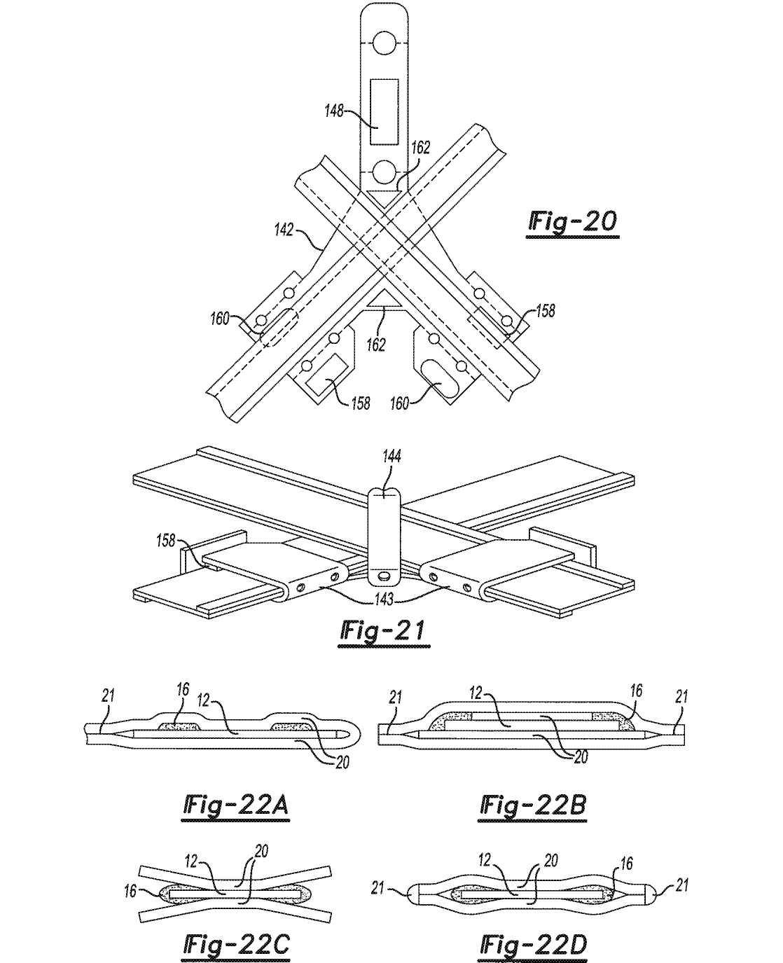

FIG. 21 illustrates the connector 140 with the band 144 folded over the intersecting tapes and tabs 143 folded to secure them. The tapes in this figure are secured and positioned only by the band 144 and the two terminal tabs 143.

### Other Connection Styles

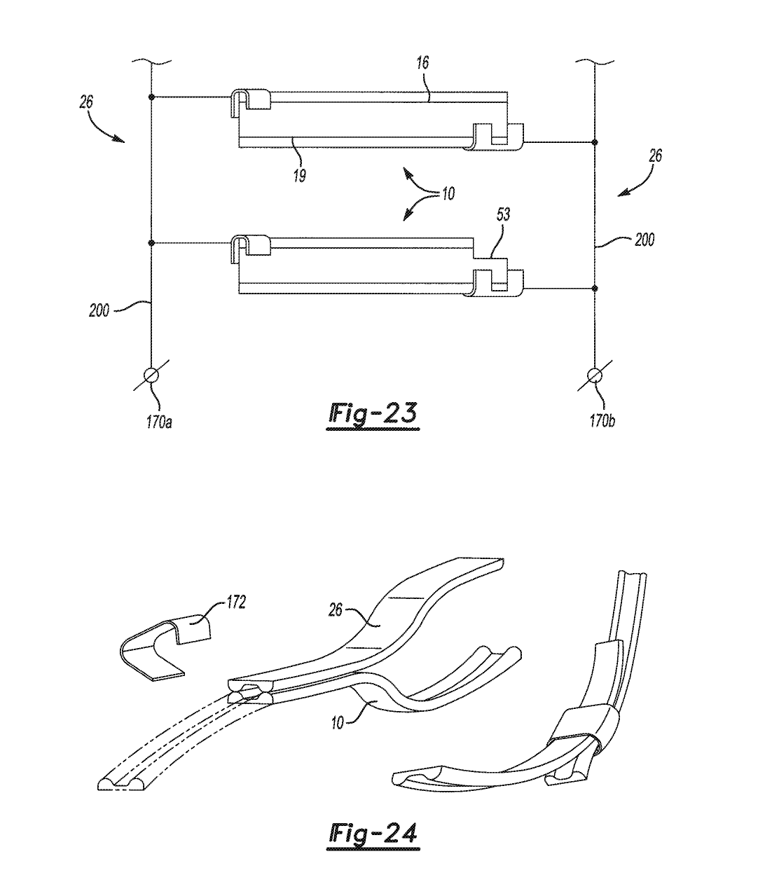

FIG. 23 illustrates an arrangement for linking multiple heating tapes 10 together. In this example, two heating tapes 10 are placed between two feeding busses 200. Specifically, one of the conductive strips 16 of each of the tapes 10 is connected to one of the feeding busses 200 and the other strip 16 is connected to the other feeding bus 200. The terminal ends 170a, 170b of the feeding busses 200 are connected to a power source to heat up the linked heating tapes 10. It should be understood that more than two heating tapes 10 can be linked between the two feeding busses 200. The feeding busses 200 ability to feed one or several heating tapes 10 depends on the size of the busses 200.

FIG. 24 illustrates another arrangement for connecting tapes together. In this arrangement, the tapes 10, 26 are placed in parallel with each other. Specifically, the conductive strips 16 of the heating tape 10 are placed facing the busses 30 of the feeding tape 26. An insulated clip 172 may be used to connect the end of the tapes 10, 26 together.

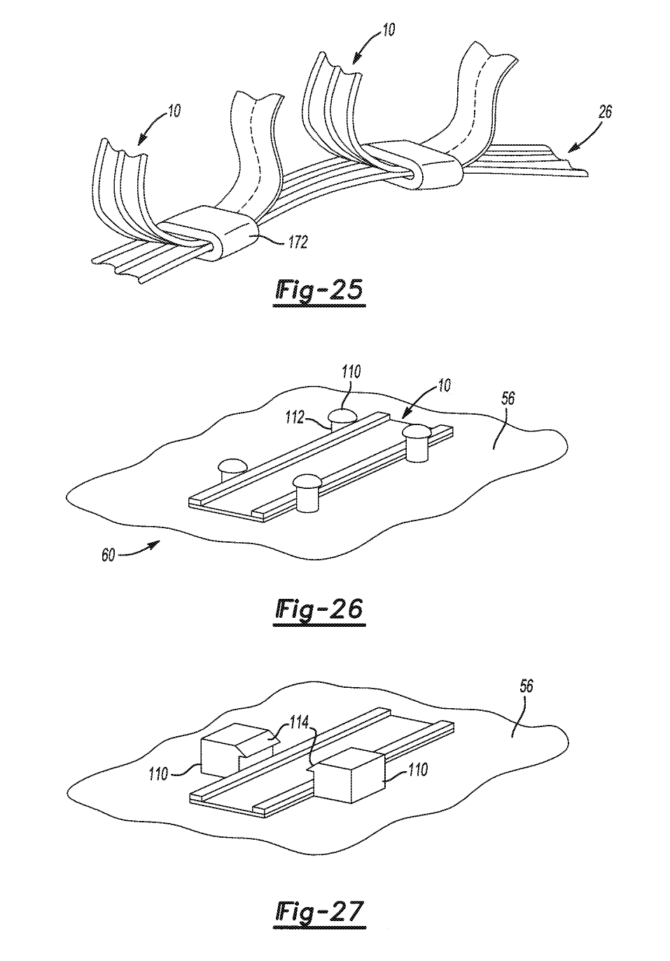

FIG. 25 illustrates yet another arrangement for connecting tapes together. In this arrangement, only one feeding tape 26 is used to feed one or more heating tapes 10. Specifically, multiple conductive strip heating tapes 10 are attached to adapted feeding tape by the clip 172 at a point between the ends of each heating tape 10.

Any mentioned connection style can be altered to connected tapes 10 having more than two conductive strips 16. The amount of openings in the film mask and pre-loading mechanisms may be increased depending on the configuration.

### Other Heating Tape Configurations

FIGS. 28(a)-(e) show the cross section of additional heating tape 10 arrangements, which may be used according to any of the techniques or structures described herein or otherwise. In particular, preferred arrangements shown in FIGS. 28(a) and 28(e) show the base film 12 enclosed between two backing layers 20. The conductive compound that forms conductive strips 16 is coated mostly on the surfaces of the backing layers 20 and only a relatively small portion is coated on the edges 14 of the base film 12. FIGS. 28(b)-(d) show a similar arrangement, but instead only include one backing layer 20 and the conductive strips 16 are wrapped differently around base film 12 and backing layer 20. As such, the heating area can be adjusted by varying the size of the strips 16 and their relation to the base film 12. In any event, the conductive strips 16 are isolated from each other by air gaps 180. The gap size shall be chosen large enough to prevent the gap 180 from accidentally closing during production.

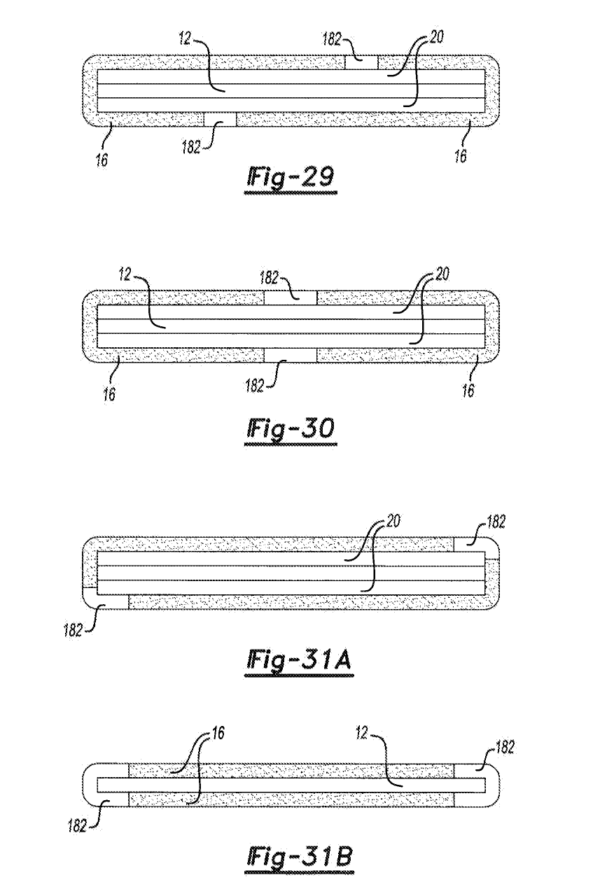

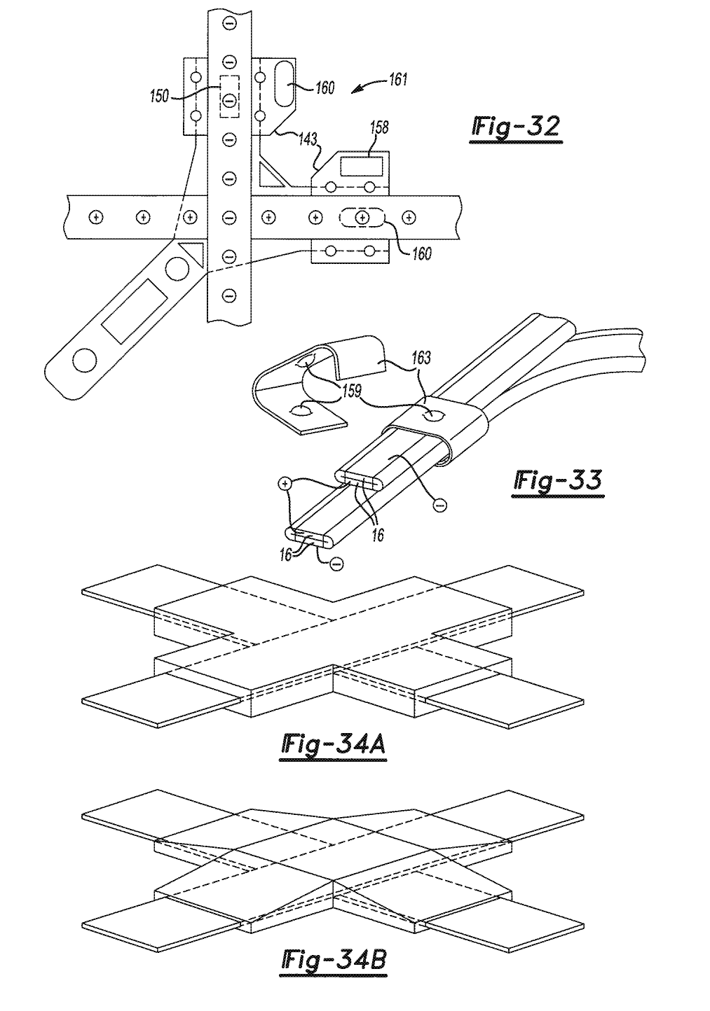

FIGS. 29-32 show additional heating tape 10 arrangements and are preferred arrangements for providing a maximum heating area. As shown, the conductive strips 16 are formed to substantially entirely surround the base film 12 and the backing layers 20. Optionally, the conductive strips 16 may be physically distanced by placing a non-conductive media 182 between them. The non-conductive media can be attached to the backing layer 20 prior to forming the conductive strips 16. The non-conductive media may adhered to the backing layer 20 using various coating or bonding methods.

These different arrangements can easily be produced by manipulating the coating method. As previously mentioned, spray or coating nozzles or rollers in the automated track system can form the conductive strips 16 by feeding (e.g., pumping) the conductive compound to the base film 12, the backing layer 20 or both. The volumetric flow rates to which the compound is being pumped out of the nozzles can be balanced relative to one another and could be linked to the speed the tape 10 as the tape 10 is being pulled through the track system so the desired thickness and width of the conductive strips 16 can be controlled.

The arrangement shown in FIG. 31B is contemplated to have the best chance to be used effectively with a high resistance polymer as a base film 12, such as, for example, a PTC polymer. In this arrangement, a current flows in a Z-direction or the thickness direction. As such, a relatively high resistance PTC (positive thermal coefficient of resistance) polymer can be utilized. This is preferred in that the thickness of the conductive strips 16 placed on opposite faces of the film 12 cause even mechanical tension/compression on the tape layers during periodic tape bending and folding.

The power density or heating ability of a heating tape structure can be chosen for different types of applications. For example, in an automotive seat heating applications, it may be desirable to provide on average approximately 650 Watts per square meter power density to a user on the seat. As such, the required heater resistance R can be determined by the following equation:

R=U*U/p=(13.8*13.5)/650=0.28 (1)

In equation (1) above, U is the typical electrical system voltage of a car and p is the power density. The required resistance in this equation is 0.28 Ohm per one square meter. In order to provide this power density by a 1 mil (0.025 mm) thick film, the film material has to have resistivity r determined by the following equation:

r=R*S/h [Ohm*m] (2)

In equation (2) above, S is an area of 1 square meter and h is the film's thickness equal to 0.000025 m. The following results:

r=0.28*1/0.000025=11200 Ohm*m (3)

Many applications require a wide range of a power/heating film thickness. The most demanded range and most preferred is a power that varies from four times above the 650 Watt per square meter and two times less the 650 Watt per square meter (i.e. from 325-2600 Watt per square meter). The thickness of the film can range from 0.025-0.125 mm. Considering the range of the film's thickness, the resistivity range can be from 500-25000 Ohm*meter.

FIG. 33 is a top view of the simplified OEM connector for connecting the tapes with a z-direction current in parallel. Two tapes are contacting each other by a single polarity strip. The opposite polarity strips are connected via a band having non-insulated bulges that squeeze the tapes by contacting the opposite polarity strips. Edges of the tape can be insulated, for example, by coating.

FIGS. 34(a) and 34(b) are perspective views of the connector being encapsulated by an enclosure 210. The enclosure 210 can be of any shape or design suitable for the heating tape arrangement.

The above mentioned arrangements may be connected by the various connectors disclosed in this whole description. However, the connectors used for these arrangements must have conduits generally on the faces of the base film 12 for connecting the strips 16 together.

It should further be understood that the heating tapes 10 and feeding tapes 26 of the present invention may be used for additional purposes, such as transmitting or receiving electrical field for the occupant recognition or other safety security systems, feeding imbedded sensors or chips, transferring data, or other computer and non-computer applications where traditional wires or cables are employed.

With reference to FIG. 36, it can be particularly desirable to have a tape with opposing conductive strips layered upon the base film. As shown, first and second conductive strips 302, 304 have been layered (e.g., sprayed or otherwise coated) upon a first surface 306 of a base film 310 while third and fourth conductive strips 322, 324 have been layered (e.g., sprayed or otherwise coated) upon a second opposing surface 326 of the film 310. As can be seen, the film 310 is sandwiched between the first strip 302 and third strip 322 and between the second strip 304 and fourth strip 324. Such a configuration, can improve heating ability and/or efficiency. For example, it is contemplated that the current splits between the opposed heating strips thereby increasing the heated area of the base film, reducing the voltage drop along these conductive strips or both for increasing heating power density and/or allowing for longer tape lengths.

Referring back to FIG. 35, as discussed previously, the tape can be formed in a continuous process by feeding the tape to an automated system. In the embodiment shown, openings 330 (e.g., through-holes) have been formed in the film 310 such that, upon printing, the opening fill with conductive material of the strips 302, 304, 322, 324. 324. Such filling can form interconnects that provide or improve electrical communication between opposing conductive strips. Interconnects like these or otherwise formed interconnects can be particularly desirable if the tape has third and forth conductive strips 322 and 324 made on a tape dielectric backing 340 (see FIG. 36 for the illustration). Other interconnects can include, for example and amongst others, clips formed of metal (e.g., metal foil) and/or conductive compound that patches and overlaps heated tape edges in various locations at the ends or along the tapes.

To ease manufacturing, with reference to FIG. 37, it can be desirable to include backing layers 340 upon the film 310 such that the opposing strips 302, 304, 322, 324 can be layered on the film 310 such that the placement of those strips can be within larger tolerances. Backing layers 340 determine the distance between the conductive strips. It is contemplated that the backing layers could be also formed by non-conductive coating.

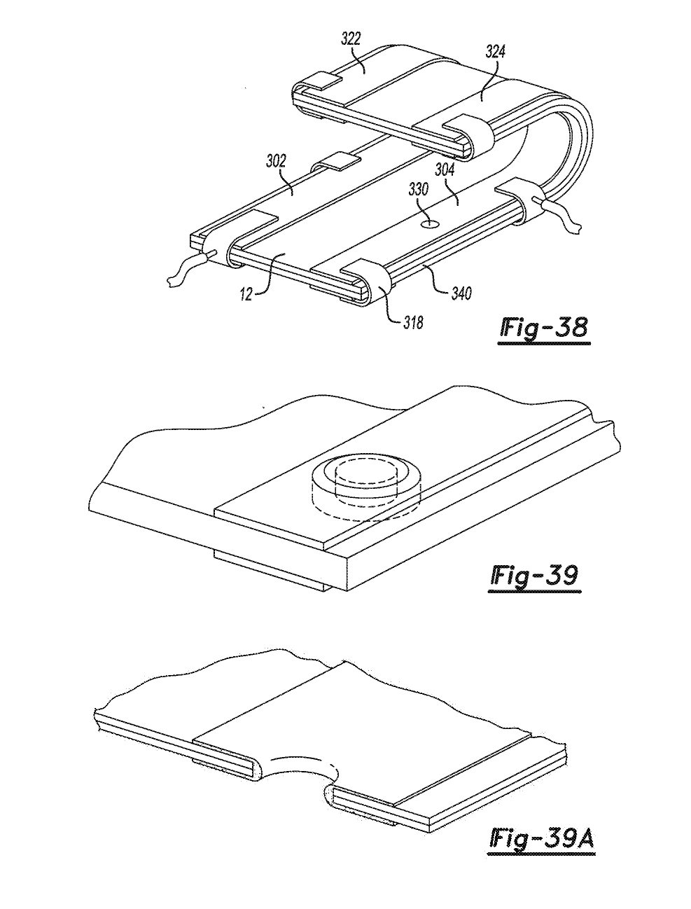

With reference to FIG. 38, it may be desirable to include multiple electrical connections along a length of the tape. Moreover, it may be desirable to have conductive strips on opposite surfaces of the tape even where the resistive film is coextensive with a dielectric backing layer.

With reference to FIG. 39, it may also be desirable, particularly for embodiments having conductive strips on opposite surfaces to have an interconnection of another conductive material extending through an opening (e.g., through-hole) of the film to electrically interconnect the strips. Such material may fill the entire opening or may fill part of (e.g., be annular within) the opening as shown in FIG. 39A. It can be important, for example, to use such a configuration for tapes with conductive strips on an insulated backing layer for providing desired current distribution.

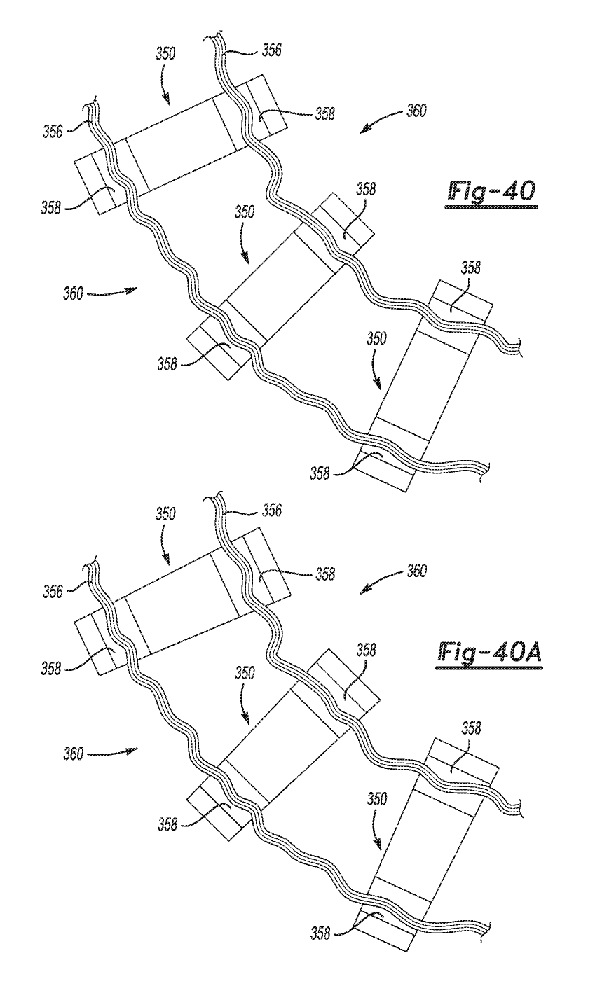

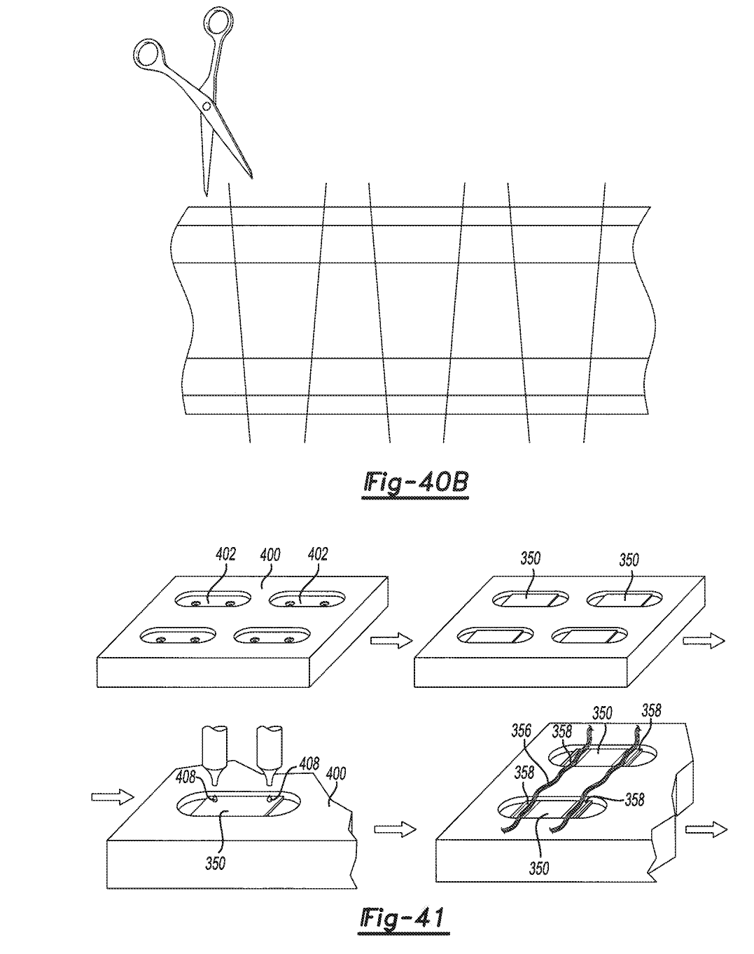

In yet another embodiment shown in FIG. 40, it is contemplated that the tape may include multiple different sections 350 spaced apart from each other and interconnected by secondary connectors 356. As can be seen, the secondary connectors 356 contact and/or interconnect portions 358 of the electrically conductive strips 360. Such contact and/or interconnection can be achieved through mechanical connectors (e.g., rivets), adhesives (e.g., conductive adhesives), soldering, fusing, ultrasonic welding, integration of the connectors 356 into the material of the portions 358 or otherwise. The secondary connectors 356 could be formed of a variety of materials such as metal, conductive polymers or the like. In one preferred embodiment, the secondary connectors 356 are formed of a conductive textile (e.g., metallized polymer fibers). The conductive textile can be in a back and forth configuration such as being relatively loosely braided or woven, being zig-zag or generally meandering back and forth such that pulling at ends of the textile allows some degree of straightening of the back and forth configuration. The conductive textile could employ or be made exclusively of carbon threads, a mixture of conductive and non-conductive filaments, colored filaments to aid positioning, conductive yarn, loosely braided cable (e.g., metal cable) or yarn or conductive or metallized fibers or filaments. Such materials can be low stretch or have the ability for a relatively higher degree of stretch.

With reference to FIG. 41, there is illustrated an exemplary process of forming a heating tape with secondary connectors. As can be seen, a support 400 is provided with cavities 402 suitable for receiving sections 350 of the base film of the tape. The sections 350 may be held in place by, for example, vacuum pressure. Then conductive material 408 is layered upon the sections 350 at ends thereof for forming the portions 358 of the conductive strips 360. At the same time or thereafter, secondary connectors 356 are associated with (e.g., contacted with and/or connected to) the portions 358 of the conductive strips 360. Preferably, the portions 358 are allowed to cure while in contact with the secondary connectors 356 for assisting in connecting the portions 358 to the connectors 356.

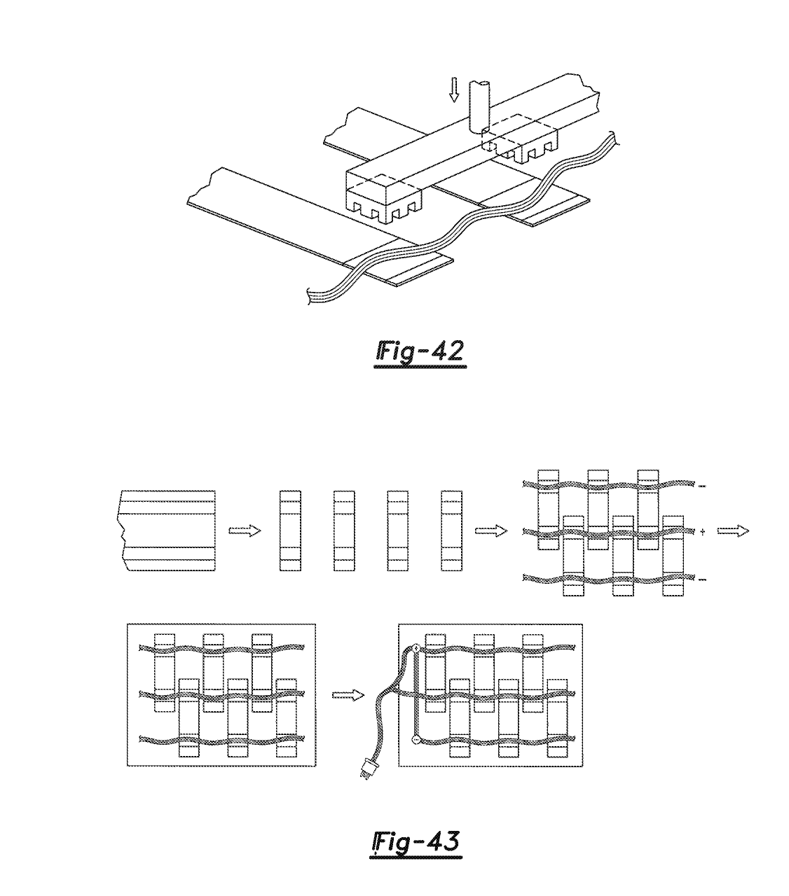

In an alternative embodiment and with reference to FIG. 42, a tool, which may be a ventilated porous tool (e.g., having ventilating fins), may be used to press the secondary connectors into contact with the portions of the conductive strips. In another alternative embodiment and with reference to FIG. 43, a tape may be cut into sections and have the secondary connectors layered (e.g., laminated) with the portions of the conductive strips. During such lamination, the secondary connectors may be pressed into the portions of the conductive strips and the sections of the tape with the secondary connectors may be laminated to a substrate. Such lamination can be assisted by using heat (e.g., hot air for potentially curing the conductive strips) and rollers for providing more robust connections between the portions of the conductive strips and the secondary connectors. Whatever process is employed, it may be desirable to pre-wet the material of the secondary connectors with, for example, the conductive material of the portions of the conductive strips prior to curing of the conductive material or other connection of the secondary connectors with the portions.

As another example, FIGS. 40A and 40B show a heating tape structure similar to that show in FIG. 40 can be arranged in a curved configuration (e.g., for adapting to curves substrates, articles of manufacture (e.g., seat cushions)). The sections are cut such that they become progressively smaller or narrower in dimension from side to side traveling from on portion of the conductive strips to the other portion of the conductive strips (e.g., form a trapezoid, are tapered, become narrower). The smaller or narrower sides of the sections are then located on the outer periphery of the curve to achieve a more consistent power density across whole heated area served by heated tape sections. As shown, in FIG. 40B, it may be possible to cut the sections into trapezoid shapes without producing any significant scrap tape.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

What is claimed is:

1. A process of forming and/or applying a heating tape structure, comprising:
providing a base film strip in a continuous manner, the base film having a first edge and a second edge, wherein:
i. the first edge and second edge extends along opposite sides of the base film strip; and
ii. the base film is formed of a resistive polymer; and
moving the base film strip along an automated system and layering a first strip and a second strip of conductive material along a surface of the base film as the base film strip is moved along the automated system thereby forming a heating tape, wherein:
i. the first strip of conductive material is spaced apart from the second strip of conductive material;
ii. the first strip of conductive material is adjacent the first edge of the base film strip and the second strip of conductive material is adjacent the second edge of the base film strip;
iii. the first strip of conductive material and the second strip of conductive material are formed of conductive polymeric material; and
iv. electrical current flows through the first conductive strip, the second conductive strip and the base film strip when the first conductive strip and the second conductive strip are electrically connected to a power source such that the base film strip produces heat.

2. A process as in claim 1 wherein the heating tape, the film or both have a width and a thickness and the length is at least twice the width

3. A process as in claim 1 wherein the heating tape, the film or both have a width and a thickness and the length is at least eight times the width

4. A process as in claim 1 wherein a dielectric backing layer is coextensive with the base film.

5. A process as in claim 1 further comprising an adhesive layer coextensive with the base film.

6. A process as in claim 1 wherein the conductive strips are discontinuous and include sections that are connected by secondary connectors.

7. A process as in claim 1 further comprising layering a third strip of conductive material along the surface of the base film.

8. A process as in claim 1 wherein a filament is at least partially disposed within the first strip of conductive material.

9. A process as in claim 1 wherein the heating tape structure includes multiple connected heating tapes.

10. A process as in claim 1 further comprising a carrier wherein the tape is attached to the carrier.

11. A process as in claim 1 further comprising connectors electrically connecting the tape to the power source of an automotive vehicle or to another heating tape.

12. A process of forming and/or applying a heating tape structure, comprising:
providing a base film strip in a continuous manner, the base film having a first edge and a second edge, wherein:
i. the first edge and second edge extends along opposite sides of a the base film strip; and
ii. the base film is formed of a resistive polymer; and
moving the base film strip along an automated system and layering a first strip and a second strip of conductive material along a first surface of the base film as the base film strip is moved along the automated system and layering a third strip and a fourth strip of conductive material along a second surface of or adjacent the base film thereby forming a heating tape, wherein:
i. the first strip of conductive material is spaced apart from the second strip of conductive material;
ii. the first strip of conductive material is adjacent the first edge of the base film strip and the second strip of conductive material is adjacent the second edge of the base film strip;
iii. the first strip of conductive material and the second strip of conductive material are formed of conductive polymeric material; and
iv. electrical current flows through the first conductive strip, the second conductive strip and the base film strip when the first conductive strip and the second conductive strip are electrically connected to a power source such that the base film strip produces heat; and
v. the first surface is opposite the second surface such that the base film is sandwiched between the first and third strips of conductive material and between the second and fourth strips of conductive material.

13. A process as in claim 12 further comprising providing an adhesive layer coextensive with the base film, wherein the heating tape, the film or both have a width and a thickness and the length is at least twice the width and wherein

14. A process as in claim 13 wherein a dielectric backing layer is coextensive with the base film and wherein the heating tape, the film or both have a width and a thickness and the length is at least eight times the width

15. A process as in claim 12 wherein the tape along with the conductive strips are divided into sections and connected by secondary connectors.

16. A process as in claim 12 wherein a filament is at least partially disposed within the first strip of conductive material.

17. A process as in claim 12 wherein the heating tape structure includes multiple connected heating tapes.

18. A process as in claim 12 further comprising a carrier wherein the tape is attached to the carrier.

19. A process as in claim 13 further comprising connectors electrically connecting the tape to the power source of an automotive vehicle.

20. A process of forming and/or applying a heating tape structure, comprising:
providing a base film strip in a continuous manner, the base film having a first edge and a second edge, wherein:
i. the first edge and second edge extends along opposite sides of a the base film strip; and
ii. the base film is formed of a resistive polymer; and
moving the base film strip along an automated system and layering a first strip and a second strip of conductive material along a first surface of the base film as the base film strip is moved along the automated system and layering a third strip and a fourth strip of conductive material along a second surface of the base film thereby forming a heating tape, wherein:
i. the first strip of conductive material is spaced apart from the second strip of conductive material;
ii. the first strip of conductive material is adjacent the first edge of the base film strip and the second strip of conductive material is adjacent the second edge of the base film strip;
iii. the first strip of conductive material and the second strip of conductive material are formed of conductive polymeric material; and
iv. electrical current flows through the first conductive strip, the second conductive strip and the base film strip when the first conductive strip and the second conductive strip are electrically connected to a power source such that the base film strip produces heat;
v. the first surface is opposite the second surface such that the base film is sandwiched between the first and third strips of conductive material and between the second and fourth strips of conductive material; and
vi. the tape structure is adhesively secured to a portion of a seat of an automotive vehicle either directly or through a substrate selected from a screen like material, a stretchable material or both.

21. A process as in claim 20 wherein the heating tape is cut in multiple sections that are interconnected by secondary connectors and the sections have a dimension from side to side of the sections and the dimension becomes smaller from one conductive portion of the first conductive strip to a conductive portion of the second conductive strip and wherein the sections are attached to a stretchable and air permeable carrier material and wherein the secondary connectors provide slack that allows the connectors to be elongated.

22. A process as in claim 1 further comprising cutting the heating tape into multiple sections and interconnecting the multiple sections with secondary connectors and attaching the secondary connectors at multiple locations to a carrier substrate thereby allowing the heating tape to adapt its shape in an automotive vehicle seat or other environment that is deformed during use such that the tape avoids some degree of tension or compression forces that it might otherwise experience.

23. A process as in claim 22 wherein the heating tape is laminated between at least two layers of carrier substrate and the layers are solid, perforated or screen-like.

24. A process as in claim 23 wherein the two layers are connected to each other in a manner that still allows for movement of the sections, the secondary connectors or both between the layers.
